(19) United States
(12) Patent Application Publication
(10) Pub. No.: US 2006/0169488 A1
(43) Pub. Date: Aug. 3, 2006

(54) Circuit board mounted with surface mount type circuit component and method for producing the same

(75) Inventor: Kenji Kaji, Tokyo (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/341,637

(22) Filed: Jan. 30, 2006

(30) Foreign Application Priority Data
Jan. 31, 2005 (JP) 2005-024455

(51) Int. Cl. H05K 1/18

(52) U.S. Cl. 174/260; 361/768

(57) ABSTRACT

A circuit board mounted with a surface mount type circuit component, including: a circuit board body mounted with the surface mount type circuit component, at least a part of a top surface of the surface mount type component being exposed to ambient air; and a reinforcing plate having an outer size larger than that of a mount surface of the surface mount type circuit component.

### CROSS-REFERENCE TO RELATED APPLICATIONS

This application is based upon and claims the benefit of priority from the prior Japanese Patent Application No. 2005-024455, filed on Jan. 31, 2005; the entire contents of which are incorporated herein by reference.

### BACKGROUND

1. Field

The present invention relates to a circuit board mounted with a semiconductor circuit component having a surface mount type package, and a method for producing the circuit board mounted with the semiconductor circuit component. It particularly relates to a circuit board mounted with a surface mount type circuit component configured so that electrodes formed on the bottom of the package are connected to pads on the board through metal bumps such as solder balls, and a method for producing the circuit board mounted with the surface mount type circuit component.

2. Description of the Related Art

A wide variety of such packages serving as semiconductor circuit components to be mounted on circuit boards have advanced in recent years so that surface mount type leadless packages which do not use any lead or pin for electric connection to the boards have been put into practical use broadly.

For example, a BGA (Ball Grid Array) package, an LGA (Land Grid Array) package, etc., are used as such surface mount type leadless packages. In the BGA package, connection terminals are formed in such a manner that solder balls are attached to electrodes (pads) which are formed, for example, as a grid array, on the bottom of the package so as to be connected to an external circuit. In the LGA package, pads (lands) formed as a grid array on the bottom of the package are used directly as connection terminals.

There is also known a CSP (Chip Size Package) having substantially the same size as that of a bare chip constituting a semiconductor. The CSP can be configured so that pads are provided on the bottom of the package and connected to pads of a circuit board through solder balls or other metal bumps.

The BGA package is mounted on a circuit board by so-called reflow soldering which is performed in such a manner that soldering is performed by heating the solder balls while the solder balls are brought into contact with pads of the circuit board to be connected.

The LGA package is mounted on a circuit board through a socket provided with contactors being in contact with pads formed on the bottom of the package or the LGA is mounted directly on a circuit board through solder balls attached to the pads.

The CSP can be also mounted on a circuit board substantially in the same manner as these circuit components.

When the circuit board mounted thus with the surface mount type semiconductor having no lead is attached to the inside of a housing of an electronic apparatus to use the circuit board, the circuit board is incorporated as one of constituent members of circuits in the electronic apparatus.

In a process of executing the circuit board incorporating operation, stress may be sometimes applied on the circuit board in a direction crossing a board surface or shock may be applied on the circuit board because of falling, etc. As a result, the circuit board may be warped or distorted. This may affect junction portions between the circuit component and the board, so that there is a possibility that the pads of the board will be peeled or soldered portions will be broken. There is a problem that the circuit board cannot fulfill its original function.

If the junction portions between the circuit component and the circuit board are broken thus, the circuit component has to be exchanged for a new one or the circuit board per se has to be exchanged for a new one. Accordingly, a considerably great deal of labor is required for assembling the electronic apparatus.

Particularly in recent years, there has been used the circuit board per se made of a thin material for reduction in size and thickness of the outer appearance of the electronic apparatus. In this case, the stiffness of the board is lowered so that the board is apt to be deformed by stress or shock applied externally. There is an increasing possibility that such an accident that breaking of the soldered portions of the circuit component will occur.

For example, JP-A-2001-291745 has heretofore disclosed a proposal to mount a BGA circuit component on a board through a reinforcing plate to thereby prevent soldered portions of the board from being deformed by external stress. In this proposal, the height of the board after mounting cannot be made small because the reinforcing plate is interposed between the BGA circuit component and the board. Moreover, there is a possibility that soldering will be unable to be performed surely at some places because solder balls of the BGA circuit component are soldered to electrodes of the board through holes of the reinforcing plate. It is accordingly difficult to perform soldering with high quality.

### BRIEF DESCRIPTION OF THE DRAWINGS

FIG. 1 is a perspective view for explaining a circuit board mounted with a surface mount type circuit component according to an embodiment of the invention;

FIG. 2 is a perspective view for explaining a state of the circuit board depicted in FIG. 1, as seen from the back;

FIG. 3 is a sectional view for explaining the configuration of the circuit board depicted in FIGS. 1 and 2;

FIG. 4 is a plan view of the circuit board depicted in FIGS. 1 and 2, as seen from the surface on which the circuit component is mounted;

FIG. 5 is a view for explaining a modified example of a reinforcing plate constituting the circuit board depicted in FIGS. 1 and 2;

FIG. 6 is a view for explaining another modified example of the reinforcing plate constituting the circuit board depicted in FIGS. 1 and 2;

FIG. 7 is a view for explaining a further modified example of the reinforcing plate constituting the circuit board depicted in FIGS. 1 and 2;

FIG. 8 is a perspective view for explaining a circuit board mounted with a surface mount type circuit component according to another embodiment of the invention;

FIG. 9 is a perspective view for explaining a state of the circuit board depicted in FIG. 8, as seen from the back;

FIG. 10 is a sectional view for explaining the configuration of the circuit board depicted in FIGS. 8 and 9; and

FIG. 11 is a perspective view for explaining a circuit board mounted with a surface mount type circuit component according to a further embodiment of the invention.

### DETAILED DESCRIPTION

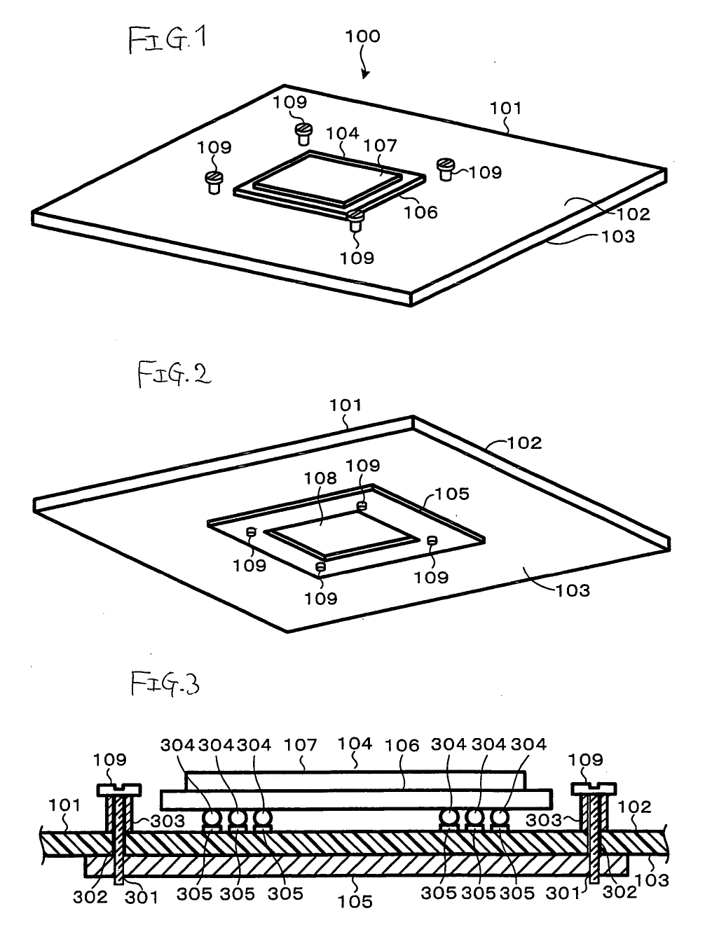

Embodiments of the invention will be described below in detail with reference to the drawings. FIGS. 1 and 2 are perspective views typically showing a circuit board 100 configured according to an embodiment of the invention. FIG. 1 shows a body of the circuit board as seen from one surface. FIG. 2 shows the body of the circuit board as seen from an opposite surface.

The circuit board 100 includes a circuit board body 101 shaped like a flat plate. The circuit board body 101 has two flat surfaces 102 and 103 opposite to each other. A BGA circuit component 104 is mounted on one flat surface 102 shown in FIG. 1. A reinforcing plate 105 is mounted on the other flat surface 103.

The BGA circuit component 104 has a base 106, and a resin member 107. The base 106 has a rectangular bottom which faces the surface 102 of the circuit board body 101. The resin member 107 seals a semiconductor chip mounted on the base 106. The base 106 is provided as a circuit board. The base 106 has pads on a surface where the semiconductor chip is mounted. The pads are connected to electrodes of the semiconductor chip. The semiconductor chip is connected to the base 106 through the pads by a flip chip mounting method or wire bonding.

The pads of the base 106 connected to the semiconductor chip are electrically connected to pads arranged as a grid array on the bottom of the base 106. Solder balls are attached to the pads arranged as a grid array to thereby form the BGA circuit component 104.

The reinforcing place 105 is made of a metal or resin high in stiffness. The reinforcing plate 105 is shaped like a flat plate similar in outer shape to the bottom of the base 106 of the BGA circuit component 104 but larger in outer size than the bottom of the base 106. An opening 108 is formed in the central portion of the reinforcing plate 105.

Screw holes are formed in four corners of the reinforcing plate 105, respectively. As shown in FIG. 1, the reinforcing plate 105 is fixed to the surface 103 of the circuit board body 101 by screws 109 from the surface 102 side of the circuit board body 101.

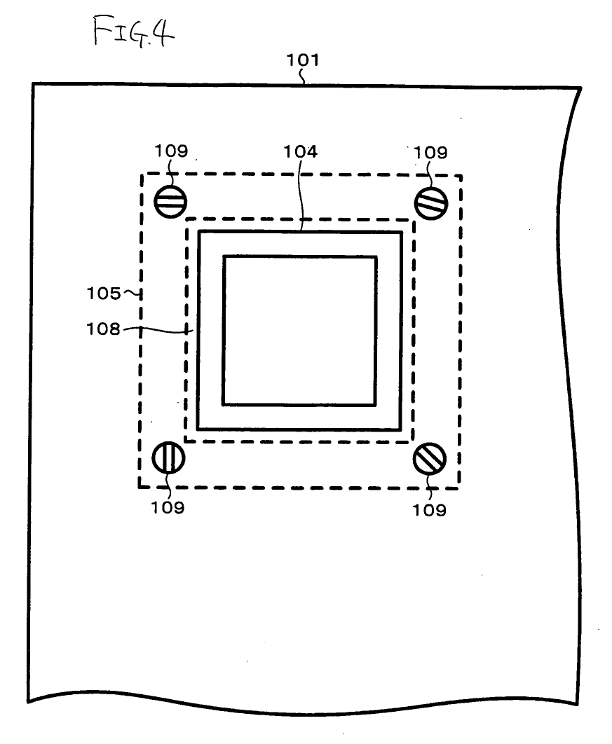

FIG. 3 is a sectional view taken along the line connecting two screws 109 and 109 in order to explain the attachment state of the reinforcing plate 105.

The screw holes 301 are provided in the reinforcing plate 105 whereas mount holes 302 are formed in the circuit board body 101 so that the screws 109 pass through the mount holes 302.

The screws 109 are inserted into the mount holes 302 through studs 303 and driven into the screw holes 301 of the reinforcing plate 105 to thereby be attached to the surface 103 of the circuit board body 101.

Incidentally, in FIG. 3, the BGA circuit component 104 has solder balls 304 attached to electrodes on the bottom of the base 106. The BGA circuit component 104 is connected to the surface 102 of the circuit board body 101 through pairs of pads 305 and solder balls 304. The pads 305 are arranged so as to correspond to the solder balls 304 respectively.

FIG. 4 is a plan view of the surface 102 of the circuit board body 101 on which the BGA circuit component 104 has been mounted. In FIG. 4, the dotted line designates the reinforcing plate 105. As shown in FIG. 4, the reinforcing plate 105 is attached to the circuit board body 101 so as to surround the BGA circuit component 104. A portion of the circuit board body 101 on which the BGA circuit component 104 is mounted is reinforced by the stiffness of the reinforcing plate 105.

In this manner, the state of connection by the solder balls 304 can be kept good because the circuit board body 101 can be restrained from being warped or deformed in the mount portion of the BGA circuit component 104 even in the case where external stress is applied on the circuit board body 101.

Although the aforementioned embodiment has shown the case where the reinforcing plate 105 has the opening 108 in its central portion, the opening 108 need not be provided if there is no component mounted on the portion of the surface 103 of the circuit board body 101 on which the reinforcing plate 105 is mounted. Also in the case where the opening 108 is provided, the shape and size of the opening 108 can be set desirably. That is, it is not necessary to provide the opening 108 with a size larger than the outer size of the bottom of the base 106 of the BGA circuit component 104 as shown in FIG. 4.

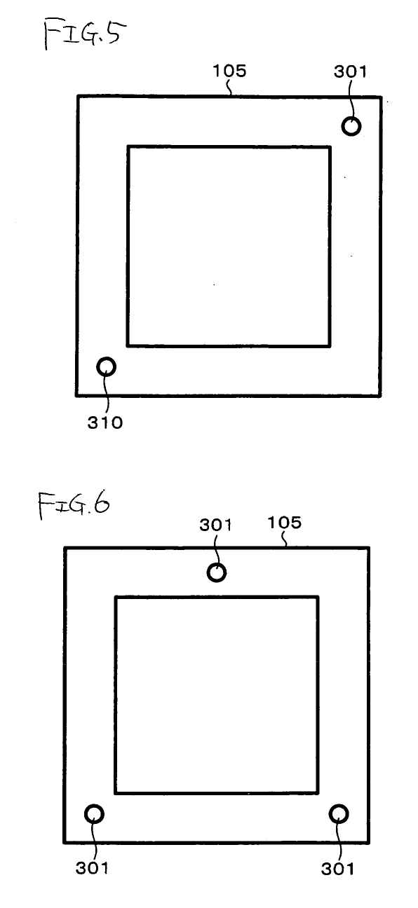

Although the above description has shown the case where four screws are used for attaching the reinforcing plate 105 to the circuit board body 101, it is not necessary to use four screws. As shown in FIG. 5, two screw holes 301 may be provided on a diagonal line so that screwing can be made. Or, as shown in FIG. 6, three screw holes 301 may be provided so that screwing can be made.

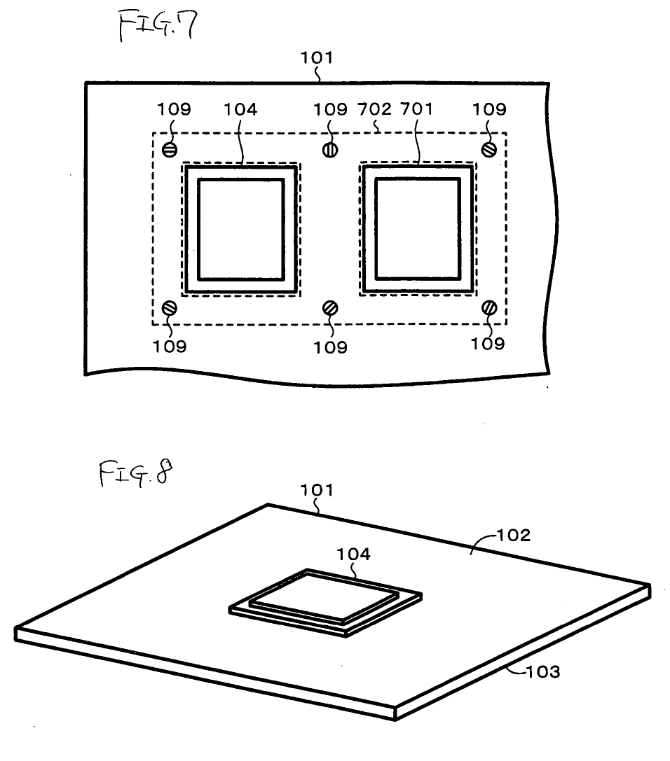

In the case where BGA circuit components are mounted adjacently, the reinforcing plate can be formed so as to correspond to the number of the BGA circuit components. In an embodiment shown in FIG. 7, in the condition that a BGA circuit component 104 and another BGA circuit component 701 are mounted adjacently, a reinforcing plate 702 is formed so as to surround portions of the circuit board body 101 on which the two BGA circuit components 104 and 701 are mounted.

When the reinforcing plate 702 shown in FIG. 7 is applied, a wide area of the circuit board body 101 can be reinforced so that deformation of the circuit board body 101 can be restrained more effectively.

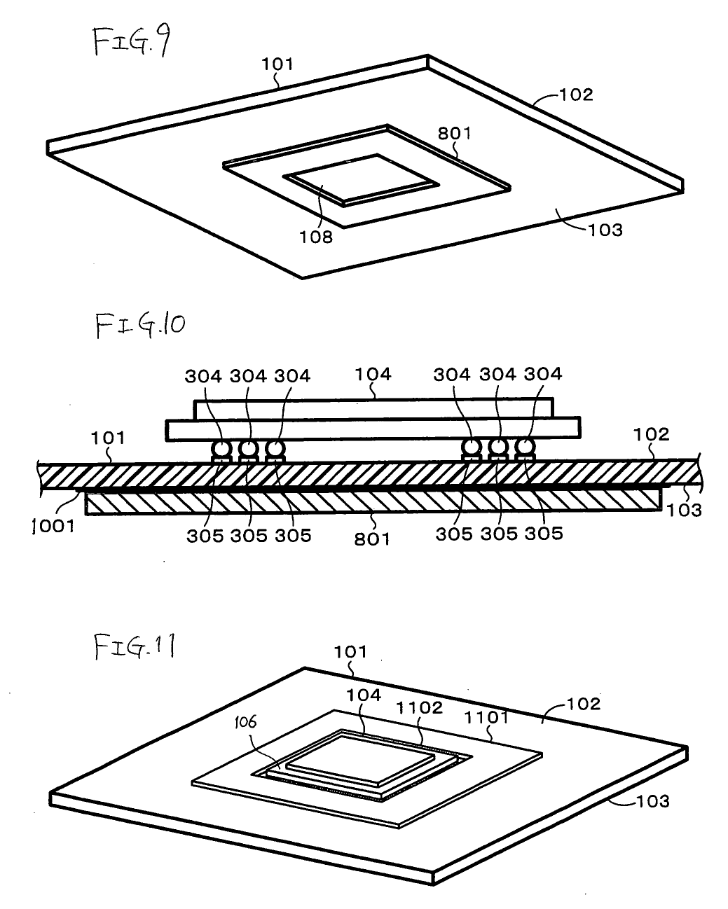

FIGS. 8 and 9 are perspective views for explaining another embodiment of the invention. FIG. 8 is a view of the circuit board body 101 as seen from the surface 102 side. FIG. 9 is a view of the circuit board body 101 as seen from the other surface 103 side.

In the embodiment shown in FIGS. 8 and 9, a reinforcing plate 801 is attached onto the surface 103 of the circuit board body 101 by an adhesive agent. In this case, for example, a thermosetting adhesive agent may be used as the adhesive agent.

FIG. 10 is a sectional view showing a state in which the reinforcing plate 801 and the circuit board body 101 depicted in FIGS. 8 and 9 are cut. As shown in FIG. 10, the reinforcing plate 801 is attached onto the surface 103 of the circuit board body 101 by an adhesive agent 1001.

According to this embodiment, there is an effect that assembling can be made easy because screwing is not required.

Although the aforementioned embodiments have shown the case where the reinforcing plate is formed so as to be attached onto the surface 103 of the circuit board body 101 opposite to the surface 102 on which each BGA circuit component is mounted, the invention may be applied to the case where the reinforcing plate is attached onto the same surface as that on which the BGA circuit component is mounted.

FIG. 11 is a perspective view for explaining an embodiment in which a reinforcing plate is attached onto the same surface as that on which the BGA circuit component is mounted.

As shown in FIG. 11, the reinforcing plate 1101 has an opening 1102 with a size larger than the outer size of the base 106 of the BGA circuit component 104. The reinforcing plate 1101 is attached onto the circuit board body 101 by an adhesive agent so that the BGA circuit component 104 is located in the inside of the opening 1102.

Also in this embodiment, the portion of the circuit board body 101 on which the BGA circuit component 104 is mounted can be restrained from being deformed by external stress because the stiffness of the portion of the circuit board body 101 on which the BGA circuit component 104 is mounted can be improved. Accordingly, there is no large stress applied on junction portions between the BGA circuit component 104 and pads of the circuit board body 101, so that an accident such as destruction of the junction portions can be prevented.

Although the above description has shown the case where a BGA circuit component is used as an example of the circuit component, the invention can be applied to a circuit board on which a circuit component such as an LGA circuit component or a CPS circuit component, as well as the BGA circuit component, is mounted.

For example, an LGA circuit component is often used so that a socket for mounting the circuit component is connected to pads of a circuit board through solder balls. In this case, the junction portions have the same problem as in the BGA circuit component. Or the way of use to connect the LGA circuit component to the circuit board through metal bumps without use of any socket may be conceived. In this case, there is the same problem as in the BGA circuit component.

The way of use to connect a CSP circuit component to a circuit board through metal bumps may be also conceived. In this case, there is the same problem as in the BGA circuit component.

The invention can be applied to a circuit board on which another surface mount type circuit component having leads such as QFP (Quad Flat Package) than the surface mount type circuit component having no lead is mounted.

As described above, the circuit board mounted with the surface mount type circuit component according to the invention is configured so that the reinforcing plate is attached onto a surface of the circuit board on which the circuit component is mounted or onto a surface of the circuit board opposite to the surface on which the circuit component is mounted so that the reinforcing plate surrounds the portion on which the circuit component is mounted. For this reason, the portion of the circuit board on which the circuit component is mounted can be restrained from being deformed by external stress. Accordingly, stress applied on the junction portions between the circuit component and pads of the board can be reduced, so that bonding accuracy can be improved.

Incidentally, the invention is not limited the aforementioned embodiments. Various modifications can be made on the invention without departing from the gist of the invention. For example, the reinforcing plate may be made of a plate-like material having a predetermined thickness or may be made of a sheet-like material.

Incidentally, the present invention is applicable to a circuit board in which at least a part of the top surface of a surface mount type component is exposed to ambient air. The ambient air may be the outside air when the circuit board has not been installed in an electronic apparatus yet. The ambient air may be the air inside the electronic apparatus when the circuit board has been installed in the electronic apparatus.

What is claimed is:

1. A circuit board mounted with a surface mount type circuit component, comprising:
a circuit board body mounted with the surface mount type circuit component, at least a part of a top surface of the surface mount type component being exposed to ambient air; and
a reinforcing plate having an outer size larger than that of a mount surface of the surface mount type circuit component.

2. The circuit board mounted with a surface mount type circuit component according to claim 1, wherein the reinforcing plate is attached onto a surface of the circuit board body opposite to a portion where the surface mount type circuit component is mounted.

3. The circuit board mounted with a surface mount type circuit component according to claim 1, wherein the reinforcing plate has an opening for storing the surface mount type circuit component in a substantially central portion of the reinforcing plate, and the reinforcing plate being attached onto a surface of the circuit board body on which the surface mount type circuit component is mounted, so that the reinforcing plate surrounds the surface mount type circuit component.

4. The circuit board mounted with a surface mount type circuit component according to claim 1, wherein the reinforcing plate is attached to the circuit board body so that an outer edge of the mount surface of the surface mount type circuit component is included in a projected area made of an outer edge of a circuit board mount surface of the reinforcing plate.

5. The circuit board mounted with a surface mount type circuit component according to claim 1, further comprising means for attaching the reinforcing plate to the circuit board body.

6. The circuit board mounted with a surface mount type circuit component according to claim 1, wherein the surface mount type circuit component comprises a plurality of surface mount type circuit components mounted adjacently; and
the reinforcing plate is attached to the circuit board body so that outer edges of mount surfaces of the surface mount type circuit components are included in a projected area made of an outer edge of a circuit board mount surface of the reinforcing plate.

7. The circuit board mounted with a surface mount type circuit component according to claim 1, wherein the surface mount type circuit component is a BGA circuit component.

8. The circuit board mounted with a surface mount type circuit component according to claim 1, wherein the surface mount type circuit component is an LGA circuit component.

9. The circuit board mounted with a surface mount type circuit component according to claim 1, wherein the surface mount type circuit component is a CSP circuit component.

10. A method of producing a circuit board mounted with a surface mount type circuit component, comprising the steps of:
mounting the surface mount type circuit component on a circuit board body; and
attaching a reinforcing plate onto a surface of the circuit board body opposite to a portion where the surface mount type circuit component is mounted, the reinforcing plate having an outer size larger than that of a mount surface of the surface mount type circuit component.

11. A method of producing a circuit board mounted with a surface mount type circuit component, comprising the steps of:
mounting the surface mount type circuit component on a circuit board body; and
attaching a reinforcing plate onto a surface of the circuit component body on which the surface mount type circuit component is mounted, so that the reinforcing plate surrounds the surface mount type circuit component, the reinforcing plate having an outer edge size larger than that of a mount surface of the surface mount type circuit component, the reinforcing plate having an opening for storing the surface mount type circuit component in a substantially central portion of the reinforcing plate.

12. The method of producing a circuit board mounted with a surface mount type circuit component according to claim 10, wherein the reinforcing plate is attached to the circuit board body so that an outer edge of the mount surface of the surface mount type circuit component is included in a projected area made of an outer edge of a circuit board mount surface of the reinforcing plate.

13. The method of producing a circuit board mounted with a surface mount type circuit component according to claim 11, wherein the reinforcing plate is attached to the circuit board body so that an outer edge of the mount surface of the surface mount type circuit component is included in a projected area made of an outer edge of a circuit board mount surface of the reinforcing plate.
